(19) United States
(12) Patent Application Publication
(10) Pub. No.: US 2023/0298823 A1
(43) Pub. Date: Sep. 21, 2023

(54) ELECTRIC DEVICE

(71) Applicant: DENSO CORPORATION, Kariya-city (JP)

(72) Inventors: Kouichi FURUKAWA, Kariya-city (JP); Shuhei HISADA, Kariya-city (JP)

(73) Assignee: DENSO CORPORATION, Kariya-city (JP)

(21) Appl. No.: 18/322,708

(22) Filed: May 24, 2023

Related U.S. Application Data
(63) Continuation of application No. PCT/JP2022/000830, filed on Jan. 13, 2022.

(30) Foreign Application Priority Data
Feb. 22, 2021 (JP) 2021-026536

(51) Int. Cl. H01G 4/228; H02M 7/00; H05K 7/20

(52) U.S. Cl. CPC H01G 4/228; H02M 7/003; H05K 7/20945

(57) ABSTRACT

An electric device includes a first power supply portion having a first conductive section configured to electrically connect a power source and an electrical component and a second conductive section configured to be integrally connected to the first conductive section and extend away from the first conductive section, a second power supply portion connecting to the second conductive section, and a capacitor. A thermal resistance per unit length in a second extension direction of the second power supply portion is higher than a thermal resistance per unit length in a first extension direction of the first power supply portion.

### CROSS REFERENCE TO RELATED APPLICATIONS

The present application is a continuation application of International Patent Application No. PCT/JP2022/000830 filed on Jan. 13, 2022, which designated the U.S. and claims the benefit of priority from Japanese Patent Application No. 2021-026536 filed in Japan filed on Feb. 22, 2021, the entire disclosure of the above application is incorporated herein by reference.

### TECHNICAL FIELD

The present disclosure described herein relates to an electric device with a capacitor.

### BACKGROUND

A case mold type capacitor includes a first P-pole bus bar, a second P-pole bus bar, and a snubber capacitor.

### SUMMARY

An electric device according to one aspect of the present disclosure includes a first power supply portion having a first conductive section that electrically connects a power source and an electrical component; and a second conductive section that is integrally connected to the first conductive section and extends away from the first conductive section, a second power supply portion connected to the second conductive section, and a capacitor connected to the second power supply portion. A thermal resistance per unit length in a second extension direction of the second power supply portion is higher than a thermal resistance per unit length in a first extension direction of the first power supply portion.

### BRIEF DESCRIPTION OF DRAWINGS

FIG. 1 is a circuit diagram illustrating an in-vehicle system;

FIG. 2 is a perspective view illustrating a power conversion device on which an electric device is mounted;

FIG. 3 is a perspective view illustrating the electric device;

FIG. 4 is a perspective view of the electric device for explaining a connection form between a first power supply bus bar and a second power supply bus bar;

FIG. 5 is a perspective view illustrating a modification of the electric device;

FIG. 6 is a perspective view illustrating a modification of the electric device;

FIG. 7 is a perspective view illustrating a modification of the electric device; and

FIG. 8 is a perspective view illustrating a modification of the electric device.

### DETAILED DESCRIPTION

In an assumable example, the first P-pole bus bar is connected to one end of the second P-pole bus bar. The snubber capacitor is connected to the other end of the second P-pole bus bar. When heat is applied to the second P-pole bus bar, the temperature of the snubber capacitor may rise excessively.

Accordingly, an electric device in which the temperature rise of the capacitor is suppressed is provided.

An electric device according to one aspect of the present disclosure includes a first power supply portion having a first conductive section that electrically connects a power source and an electrical component; and a second conductive section that is integrally connected to the first conductive section and extends away from the first conductive section, a second power supply portion connected to the second conductive section, and a capacitor connected to the second power supply portion. A thermal resistance per unit length in a second extension direction of the second power supply portion is higher than a thermal resistance per unit length in a first extension direction of the first power supply portion.

According to this configuration, it is difficult to transfer heat to the capacitor. It is easy to suppress the temperature rise of the capacitor.

The following will describe embodiments for carrying out the present disclosure with reference to the drawings. In each embodiment, parts corresponding to the elements described in the preceding embodiments are denoted by the same reference numerals, and redundant explanation may be omitted. When only a part of a configuration is described in an embodiment, another preceding embodiment may be applied to the other parts of the configuration.

It may be possible not only to combine parts the combination of which is explicitly described in an embodiment, but also to combine parts of respective embodiments the combination of which is not explicitly described if any obstacle does not especially occur in combining the parts of the respective embodiments.

### First Embodiment

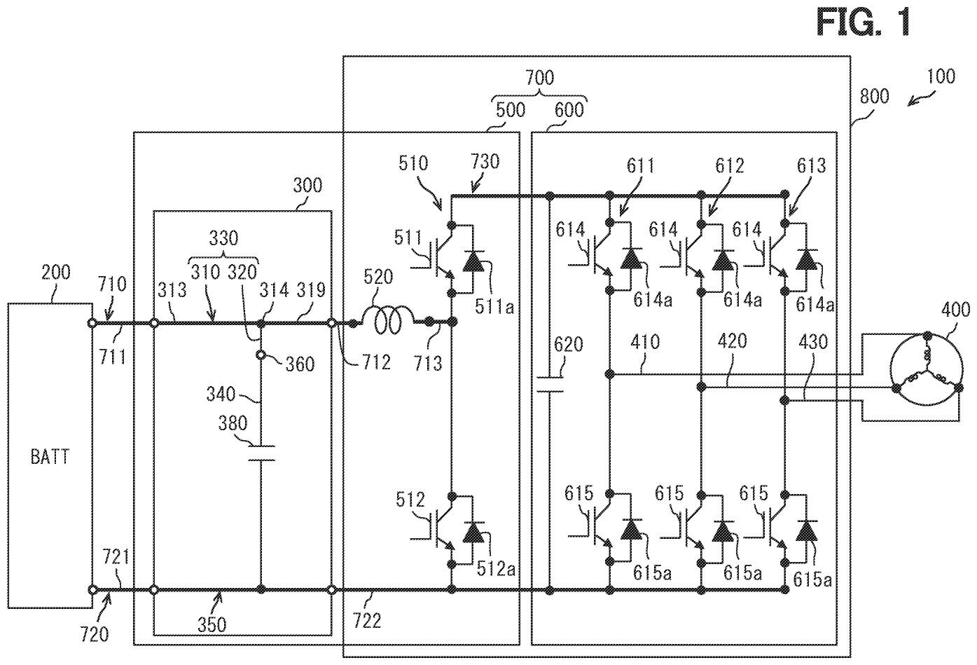

First, an in-vehicle system 100 will be described based on FIG. 1. The in-vehicle system 100 is a system for an electric vehicle. The in-vehicle system 100 has a battery 200, a motor 400, and a power converter 700. The battery 200 corresponds to a power source.

Further, the in-vehicle system 100 has a plurality of ECUs (not shown). The ECU is mounted on a circuit board. The ECUs transmit signals to and receive signals from each other via a bus wiring. The ECUs control the electric vehicle in a cooperative manner. The regeneration and power running of the motor 400 according to SOC of the battery 200 are controlled by the ECUs. SOC is an abbreviation for State Of Charge. ECU is an abbreviation of Electronic Control Unit.

The battery 200 includes a plurality of secondary batteries. The secondary batteries form a battery stack connected in series. The SOC of the battery stack corresponds to the SOC of the battery 200. As the secondary batteries, a lithium ion secondary battery, a nickel hydrogen secondary battery, an organic radical battery, or the like may be employed.

### <Power Converter>

The power converter 700 includes a converter 500 and an inverter 600. The converter 500 steps up (boosts) the DC power of the battery 200 to a voltage level suitable for the power running of the motor 400. The inverter 600 converts the DC power into an AC power. This AC power is supplied to the motor 400. Further, the inverter 600 converts the AC power generated by the motor 400 into DC power. The converter 500 steps down the DC power to a voltage level suitable for charging the battery 200.

As shown in FIG. 1, the converter 500 is electrically connected to the battery 200 via a first wiring 710 and a second wiring 720. The converter 500 is electrically connected to the inverter 600 via a third wiring 730 and the second wiring 720.

### <Converter>

The converter 500 includes an electric device 300 having a first capacitor 380, a A-phase leg 510, and a reactor 520. The first capacitor 380 corresponds to a capacitor.

The A-phase leg 510 has a first high-side switch 511 and a first low-side switch 512. A first free wheel diode 511a is connected to the first high-side switch 511. A second free wheel diode 512a is connected to the first low-side switch 512.

As shown in FIG. 1, a collector electrode of the first high-side switch 511 is connected to the third wiring 730. An emitter electrode of the first high-side switch 511 is connected to a collector electrode of the first low-side switch 512. An emitter electrode of the first low-side switch 512 is connected to the second wiring 720.

The first high-side switch 511 and the first low-side switch 512 are serially connected in order from the third wiring 730 toward the second wiring 720.

In order to simplify the subsequent description, the details of the first wiring 710 and the second wiring 720 will be described first.

The first wiring 710 is a wiring that electrically connects a positive electrode of the battery 200 and a middle point between the first high-side switch 511 and the first low-side switch 512 of the A-phase leg 510. The first wiring 710 has a first connection bus bar 711, a second connection bus bar 712, a third connection bus bar 713, and a first power supply bus bar 330. The first power supply bus bar 330 corresponds to a first power supply portion.

The first connection bus bar 711 is a wiring connected to the positive terminal of the battery 200 and the first power supply bus bar 330. The first power supply bus bar 330 is provided in the electric device 300, and includes a first conductive section 310 connected to the first connection bus bar 711 and the second connection bus bar 712, and a second conductive section 320 connected to the second power supply bus bar 340 described later. The second connection bus bar 712 is wiring connected to the first power supply bus bar 330 and the reactor 520 respectively. The third connection bus bar 713 is a wiring that connects the reactor 520 to a middle point between the first high-side switch 511 and the first low-side switch 512.

The second wiring 720 is a wiring that is connected to the negative electrode of the battery 200 and the respective low-side switches of the converter 500 and the inverter 600. The second wiring 720 has a fourth connection bus bar 721, a fifth connection bus bar 722 and a third power supply bus bar 350.

The fourth connection bus bar 721 is a wiring connected to the negative electrode of the battery 200 and the third power supply bus bar 350. The third power supply bus bar 350 is provided in the electric device 300 and is a wiring connected to the fourth connection bus bar 721, the fifth connection bus bar 722, and the other of the two electrodes provided in the first capacitor 380, respectively. The fifth connection bus bar 722 is a wiring connected to the electric device 300, and the respective low-side switches of the converter 500 and the inverter 600.

The electric device 300 has a second power supply bus bar 340 in addition to the first capacitor 380, the first power supply bus bar 330, and the third power supply bus bar 350 described above. The second power supply bus bar 340 corresponds to a second power supply portion.

One end of the second power supply bus bar 340 is connected to the second conductive section 320. The other end of the second power supply bus bar 340 is connected to one of the two electrodes of the first capacitor 380 via solder. One end of the second power supply bus bar 340 is electrically and mechanically connected to the second conductive section 320 via a joint portion 360 which will be described later.

High-frequency current noise generated in the battery 200 and the inverter 600 unintentionally flows through the first wiring 710 and the second wiring 720 described above. The first capacitor 380 is a filter capacitor for removing current noise flowing through these first wiring 710 and second wiring 720.

The high-side switch 511 and the low-side switch 512 are controlled to open and close by the ECU. The ECU generates a control signal and outputs it to a gate driver. The gate driver amplifies the control signal and outputs the amplified control signal to a gate electrode of a switch. Accordingly, the ECU steps up or down the voltage level of the DC power input to the converter 500.

The ECU generates a pulse signal as the control signal. The ECU adjusts a step-up/down level of the DC power by adjusting an on-duty ratio and a frequency of the pulse signal. The step-up/down level is determined according to the target torque of the motor 400 and the SOC of the battery 200.

When boosting the DC power of the battery 200, the gate driver alternately opens and closes the first high-side switch 511 and the first low-side switch 512.

When the first high-side switch 511 is turned off and the first low-side switch 512 is turned on, current flows from the positive electrode of the battery 200 to the first low-side switch 512 via the reactor 520. At this time, current is charged in the reactor 520.

When the first high-side switch 511 is turned on and the first low-side switch 512 is turned off, current flows from the positive electrode of the battery 200 to the first high-side switch 511 via the reactor 520. At this time, the current charged in the reactor 520 flows through the first high-side switch 511 at the same time. The current flowing through the first high-side switch 511 increases by this current. Accordingly, the DC power supplied from the battery 200 is stepped up.

On the contrary, when steeping down the DC power supplied from the inverter 600, the ECU fixes the control signal output to the first low-side switch 512 to a low level. At the same time, the ECU sequentially switches the control signal output to the first high-side switch 511 between a high level and a low level. A detailed description of stepping down the DC power is omitted.

### <Inverter>

The inverter 600 has a U-phase leg 611, a V-phase leg 612, a W-phase leg 613, and a second capacitor 620.

Each of the U-phase leg 611 to W-phase leg 613 has a second high-side switch 614 and a second low-side switch 615. A third free wheel diode 614a is connected to the second high-side switch 614. A fourth free wheel diode 615a is connected to the second low-side switch 615.

As shown in FIG. 1, a collector electrode of the second high-side switch 614 is connected to the third wiring 730. An emitter electrode of the second high-side switch 614 is connected to a collector electrode of the second low-side switch 615. An emitter electrode of the second low-side switch 615 is connected to the second wiring 720.

The second high-side switch 614 and the second low-side switch 615 are serially connected in order from the third wiring 730 toward the second wiring 720.

One of two electrodes of the second capacitor 620 is connected to the third wiring 730. The other of two electrodes of the second capacitor 620 is connected to second wiring 720.

The second capacitor 620 is a smoothing capacitor which smooths pulsating current that occurs when the AC current is rectified to the DC current. The second capacitor 620 smooths the pulsating current by repeating charging and discharging.

Furthermore, a U-phase bus bar 410 is connected to a midpoint between the second high-side switch 614 and the second low-side switch 615 provided in the U-phase leg 611. The U-phase bus bar 410 is connected to a U-phase stator coil of the motor 400.

The V-phase bus bar 420 is connected to a midpoint between the second high-side switch 614 and the second low-side switch 615 of the V-phase leg 612. The V-phase bus bar 420 is connected to a V-phase stator coil of the motor 400.

A W-phase bus bar 430 is connected to a midpoint between the second high-side switch 614 and the second low-side switch 615 of the W-phase leg 613. The W-phase bus bar 430 is connected to the W-phase stator coil of the motor 400.

When the motor 400 is powered, each of the second high-side switch 614 and the second low-side switch 615 provided in the U-phase leg 611 to the W-phase leg 613 are PWM-controlled by the control signal from the ECU. In this way, three-phase alternating current is generated in the inverter 600. When the motor 400 generates (i.e., regenerates) electricity, the ECU stops the output of the control signal, for example. As a result, AC power generated by power generation of the motor 400 passes through the diodes of the U-phase leg 611 to the W-phase leg 613. As a result, the AC power is converted to DC power.

### <Electrical Parts>

Among the constituent elements of power converter 700 described above, the A-phase leg 510, the reactor 520, the U-phase leg 611, the V-phase leg 612, the W-phase leg 613, and the second capacitor 620 are collectively referred to as an electrical component 800.

### <Mechanical Configuration of Electric Device>

Next, the mechanical configuration of the electric device 300 will be described. Hereinafter, three directions having relations orthogonal to one another will be described as an x direction, a y direction, and a z direction. In the drawings, the “directions” will not be described and simply illustrated as x, y, and z. In the drawing, the battery 200 is abbreviated as “BATT”.

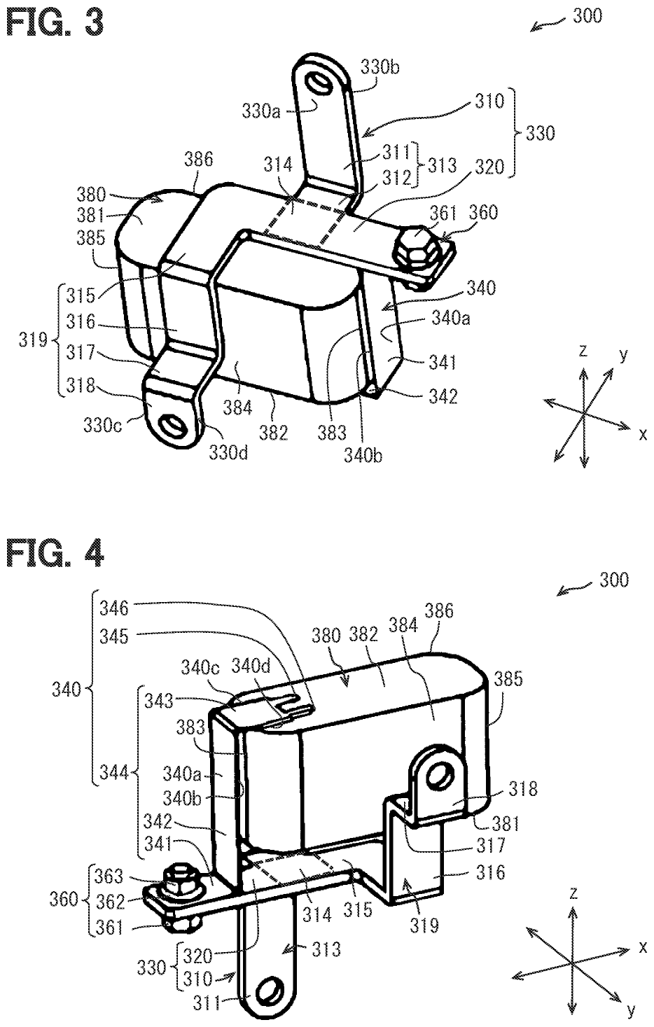

In addition to the constituent elements described above, the electric device 300 has the joint portion 360 that connects a first power supply bus bar 330 and a second power supply bus bar 340. As shown in FIGS. 3 and 4, the joint portion 360 has a bolt 361, a washer 362 and a nut 363. A specific form of connection between the first power supply bus bar 330 and the second power supply bus bar 340 via the joint portion 360 will be described later.

### <First Capacitor>

As shown in FIGS. 3 and 4, the first capacitor 380 has a substantially rectangular parallelepiped shape. The first capacitor 380 has a top surface 381 and a bottom surface 382 spaced apart in the z direction, a first capacitor surface 383 and a third capacitor surface 385 spaced apart in the x direction, and a second capacitor surface 384 and a fourth capacitor surface 386 spaced apart in the y direction.

The first capacitor surface 383, the second capacitor surface 384, the third capacitor surface 385, and the fourth capacitor surface 386 are annularly connected in a circumferential direction around the z-direction. The top surface 381 is connected to one end side in the z direction of each of the first to fourth capacitor surfaces 383 to 386. The bottom surface 382 is connected to the other end side in the z direction of each of the first to fourth capacitor surfaces 383 to 386.

The first capacitor 380 has two electrodes. One of the two electrodes in the first capacitor 380 is provided on the top surface 381. The other of the two electrodes in first capacitor 380 is provided on bottom surface 382.

### <First Power Supply Bus Bar>

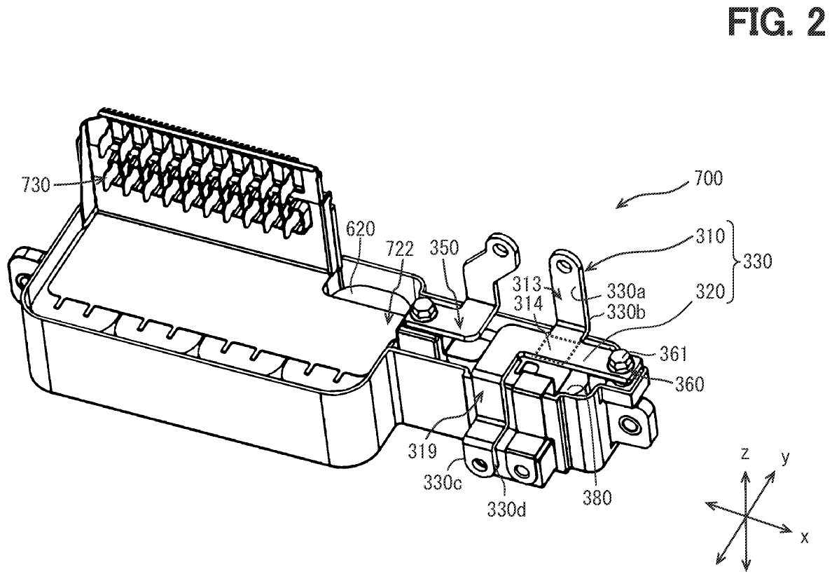

As shown in FIGS. 2 and 3, the first power supply bus bar 330 has the first conductive section 310 and the second conductive section 320. The first power supply bus bar 330 has a first main surface 330a and a second main surface 330b arranged in a direction perpendicular to its extension direction, and a first side surface 330c and a second side surface 330d aligned in a direction orthogonal to the extension direction and the alignment direction of the first main surface 330a and the second main surface 330b.

The first conductive section 310 has a first conductive connection portion 313, a second conductive connection portion 319, and a connection portion 314 connecting the first conductive connection portion 313 and the second conductive connection portion 319.

The first conductive connection portion 313 has a first connection part 311 and a second connection part 312. As shown in FIG. 3, the first connection part 311 extends in the z direction. One end of the first connection part 311 in the z direction is electrically and mechanically joined to the end of the first connection bus bar 711.

The second connection part 312 is integrally connected to the other end of the first connection part 311 in the z direction. The second connection part 312 extends in the y direction in a manner spaced apart from the first connection part 311. The connection portion 314 is integrally connected to the end of the second connection part 312 spaced apart in the y direction from the first connection part 311.

The second conductive connection portion 319 has a third connection part 315, a fourth connection part 316, a fifth connection part 317, and a sixth connection part 318.

One end of the third connection part 315 is integrally connected to the connection portion 314. The third connection part 315 extends in the x-direction away from the connection portion 314 and further extends in the y direction from its tip. The other end of the third connection part 315 is integrally connected to one end of the fourth connection part 316.

The fourth connection part 316 extends in the z direction in a manner spaced apart from the third connection part 315. The other end of the fourth connection part 316 is integrally connected to one end of the fifth connection part 317.

The fifth connection pad 317 extends in the y direction in a manner spaced apart from the fourth connection part 316. The other end of the fifth connection part 317 is integrally connected to one end of the sixth connection part 318.

The sixth connection part 318 extends in the z direction away from the fifth connection part 317. The other end in the z direction of the sixth connection part 318 is electrically and mechanically joined to the end of a second connection portion.

One end of the second conductive section 320 is integrally connected to the connection portion 314. The second conductive section 320 extends away from the connection portion 314 in the x direction. A first fastening hole penetrating through the first main surface 330a and the second main surface 330b is formed at the other end of the second conductive section 320 in the x direction. A shaft portion of the bolt 361 is passed through a first fastening hole and a second fastening hole described later. The second conduction section 320 and the second power supply bus bar 340 are electrically and mechanically joined via the joint portion 360 including the bolt 361. A specific connection form between the second conduction section 320 and the second power supply bus bar 340 will be described in detail later.

As shown in FIG. 3, a part of the second main surface 330b of each of the second connection part 312, the connection portion 314, the third connection part 315, and the second conductive section 320 faces the top surface 381 in the z direction.

As shown in FIG. 3, a part of the second main surface 330b of each of the fourth connection part 316 and the sixth connection part 318 faces the second capacitor surface 384 in the y direction.

### <Second Conductive Bus Bar>

As shown in FIG. 4, the second power supply bus bar 340 has a seventh connection part 341, an eighth connection part 342, a ninth connection part 343, a first tip part 345, and a second tip part 346. The second power supply bus bar 340 has a third main surface 340a and a fourth main surface 340b arranged in a direction perpendicular to its extension direction, and a third side surface 340c and a fourth side surface 340d aligned in a direction orthogonal to the extension direction and the alignment direction of the third main surface 340a and the fourth main surface 340b.

As shown in FIG. 4, the seventh connection part 341 extends in the y direction. A second fastening hole penetrating the third main surface 340a and the fourth main surface 340b is formed at one end of the seventh connection part 341 in the y direction. As described above, the shaft portion of the bolt 361 is passed through the first fastening hole and the second fastening hole. As described above, the second conductive section 320 and the second power supply bus bar 340 are electrically and mechanically joined via the joint portion 360 including the bolt 361. The other end of the seventh connection part 341 in the y direction is integrally connected to one end of the eighth connection part 342.

The eighth connection part 342 extends away from the seventh connection part 341 in the z direction. The other end of the eighth connection part 342 in the z direction is integrally connected to one end of the ninth connection part 343.

The ninth connection part 343 extends away from the eighth connection part 342 in the y direction. The other end of the ninth connection part 343 in the y direction is integrally connected to one end of each of the first tip part 345 and the second tip part 346.

The first tip part 345 extends in the y direction away from the ninth connection part 343. The second tip part 346 extends in the y direction away from the ninth connection part 343.

As described above, the first tip part 345 and the second tip part 346 also have third and fourth main surfaces 340a and 340b and third and fourth side surfaces 340c and 340d, respectively.

As shown in FIG. 4, the first tip part 345 and the second tip part 346 are spaced apart in the x direction. The fourth main surface 340b of each of the first tip part 345 and the second tip part 346 is connected to one of the two electrodes of the first capacitor 380 provided on the bottom surface 382 via solder.

In addition, as shown in FIG. 4, the fourth main surface 340b of the seventh connection part 341 faces part of the second main surface 330b of the second conductive section 320 in the z direction.

A part of the fourth main surface 340b of the eighth connection part 342 faces the first capacitor surface 383 in the y direction.

The fourth main surface 340b of each of a part of the ninth connection part 343, the first tip part 345, and the second tip part 346 face the bottom surface 382 in the z direction.

### <First Conductive Bus Bar and Second Conductive Bus Bar>

To simplify the description below, a direction in which each of the first main surface 330a and the second main surface 330b and the third main surface 340a and the fourth main surface 340b is arranged is referred to as a main surface direction. A direction in which each of the first side surface 330c and the second side surface 330d and the third side surface 340c and the fourth side surface 340d is arranged is referred to as a side surface direction. A direction in which each of the first power supply bus bar 330 and the second power supply bus bar 340 extends is referred to as an extension direction.

An extension direction in which the first power supply bus bar 330 extends corresponds to a first extension direction. An extension direction in which the second power supply bus bar 340 extends corresponds to a second extension direction. A direction in which the first main surface 330a and the second main surface 330b are arranged corresponds to a first orthogonal direction. A direction in which the first side surface 330c and the second side surface 330d are arranged corresponds to a second orthogonal direction. A direction in which the third main surface 340a and the fourth main surface 340b are arranged corresponds to a third orthogonal direction. A direction in which the third side surface 340c and the fourth side surface 340d are arranged corresponds to a fourth orthogonal direction.

Further, a component portion including the seventh connection part 341, the eighth connection part 342, and the ninth connection part 343 is indicated as a tenth connection portion 344. The tenth connection portion 344 is also a component portion of the second power supply bus bar 340 excluding the first tip part 345 and the second tip part 346.

First, a relationship between a separation distance between the first main surface 330a and the second main surface 330b in the main surface direction and a separation distance between the third main surface 340a and the fourth main surface 340b in the main surface direction will be described.

As shown in FIGS. 3 and 4, the separation distance between the first main surface 330a and the second main surface 330b of the first power supply bus bar 330 in the main surface direction is longer than the separation distance between the third main surface 340a and the fourth main surface 340a of the tenth connection portion 344.

The separation distance between the third main surface 340a and the fourth main surface 340b of the first tip part 345 and the second tip part 346 in the main surface direction is equal to the separation distance between the third main surface 340a and the fourth main surface 340b of the tenth connection portion 344.

The separation distance between the third main surface 340a and the fourth main surface 340b of the first tip part 345 and the second tip part 346 is shorter than the separation distance between the first main surface 330a and the second main surface 330b of the first power supply bus bar 330 in the main surface direction.

Next, a relationship between the separation distance between the first side surface 330c and the second side surface 330d in the side direction and the separation distance between the third side surface 340c and the fourth side surface 340d in the side direction will be described.

As shown in FIGS. 3 and 4, the separation distance between the first side surface 330c and the second side surface 330d of the first power supply bus bar 330 in the side direction is equal to the separation distance between the third side surface 340c and the fourth side surface 340d of the tenth connection portion 344.

The separation distance between the third side surface 340c and the fourth side surface 340d of the first tip part 345 and the second tip part 346 in the side surface direction is shorter than the separation distance between the third side surface 340c and the fourth side surface 340d of the tenth connection portion 344.

The separation distance between the third side surface 340c and the fourth side surface 340d of the first tip part 345 and the second tip part 346 in the side surface direction is shorter than the separation distance between the first side surface 330c and the second side surface 330d of the first power supply bus bar 330.

A cross-sectional area cut by a plane along each of the main surface direction and the side surface direction orthogonal to the extension direction of the tenth connection portion 344 is smaller than a cross-sectional area cut by a plane along each of the main surface direction and the side surface direction orthogonal to the extension direction of the first power supply bus bar 330.

A thermal resistance per unit length in the extension direction of the tenth connection portion 344 is higher than the thermal resistance per unit length in the extension direction of the first power supply bus bar 330.

An electrical resistance per unit length in the extension direction of the tenth connection portion 344 is higher than the electrical resistance per unit length in the extension direction of the first power supply bus bar 330.

A cross-sectional area cut by a plane along each of the main surface direction and the side surface direction orthogonal to the extension direction of the first tip part 345 is smaller than a cross-sectional area cut by a plane along each of the main surface direction and the side surface direction orthogonal to the extension direction of the tenth connection portion 344.

A cross-sectional area cut by a plane along each of the main surface direction and the side surface direction orthogonal to the extension direction of the second tip part 346 is smaller than a cross-sectional area cut by a plane along each of the main surface direction and the side surface direction orthogonal to the extension direction of the tenth connection portion 344.

A cross-sectional area cut by a plane along each of the main surface direction and the side surface direction orthogonal to the extension direction of the first tip part 345 is equal to a cross-sectional area cut by a plane along each of the main surface direction and the side surface direction orthogonal to the extension direction of the second tip part 346.

A thermal resistance per unit length in the extension direction of the first tip part 345 and the second tip part 346 is higher than the thermal resistance per unit length in the extension direction of the tenth connection portion 344.

An electrical resistance per unit length in the extension direction of the first tip part 345 and the second tip part 346 is higher than the electrical resistance per unit length in the extension direction of the tenth connection portion 344.

In summary, the cross-sectional area cut by a plane along each of the main surface direction and the side surface direction orthogonal to the extension direction of the first power supply bus bar 330 is larger than the cross-sectional area cut by any plane along each of the main surface direction and the side surface direction orthogonal to the extension direction of the second power supply bus bar 340.

In addition, a cross-sectional area cut by a plane along each of the main surface direction and the side surface direction perpendicular to the extension direction of the first power supply bus bar 330 corresponds to a first cross-sectional area. In addition, a cross-sectional area cut by a plane along each of the main surface direction and the side surface direction perpendicular to the extension direction of the second power supply bus bar 340 corresponds to a second cross-sectional area.

The thermal resistance per unit length in the extension direction of the second power supply bus bar 340 is higher than the thermal resistance per unit length in the extension direction of the first power supply bus bar 330.

The electrical resistance per unit length in the extension direction of the second power supply bus bar 340 is higher than the electrical resistance per unit length in the extension direction of the first power supply bus bar 330.

In addition, the cross-sectional area cut by a plane along each of the main surface direction and the side surface direction orthogonal to the extension direction of the first power supply bus bar 330 may be locally smaller than the cross-sectional area cut by any plane along each of the main surface direction and the side surface direction orthogonal to the extension direction of the second power supply bus bar 340.

The thermal resistance per unit length in the extension direction of the second power supply bus bar 340 may be locally smaller than the thermal resistance per unit length in the extension direction of the first power supply bus bar 330.

The electrical resistance per unit length in the extension direction of the second power supply bus bar 340 may be locally smaller than the electrical resistance per unit length in the extension direction of the first power supply bus bar 330.

Furthermore, an addition average of the thermal resistance per unit length in the extension direction of the second conductive section 320 and the thermal resistance per unit length in the extension direction of the second power supply bus bar 340 is higher than the thermal resistance per unit length in the extension direction of the first conductive connection portion 313.

The addition average of the thermal resistance per unit length in the extension direction of the second conductive section 320 and the thermal resistance per unit length in the extension direction of the second power supply bus bar 340 is higher than the thermal resistance per unit length in the extension direction of the second conductive connection portion 319.

Furthermore, an addition average of the electrical resistance per unit length in the extension direction of the second conductive section 320 and the electrical resistance per unit length in the extension direction of the second power supply bus bar 340 is higher than the electrical resistance per unit length in the extension direction of the first conductive connection portion 313.

The addition average of the electrical resistance per unit length in the extension direction of the second conductive section 320 and the electrical resistance per unit length in the extension direction of the second power supply bus bar 340 is higher than the electrical resistance per unit length in the extension direction of the second conductive connection portion 319.

### <Connection Form Between First Power Supply Bus Bar and Second Power Supply Bus Bar>

As described above, part of the second conductive section 320 and the seventh connection part 341 overlap in the z direction. The first fastening hole and the second fastening hole communicate in the z direction.

The shaft portion of the bolt 361 is passed from the second conductive section 320 toward the seventh connection part 341 through a communicating hole that communicates the first fastening hole and the second fastening hole. As shown in FIGS. 3 and 4, the head portion of the bolt 361 is provided on the side of the second conductive section 320 such that the head portion of the bolt 361 contacts the second conductive section 320. A spiral groove is formed in the shaft portion in the circumferential direction around the z direction.

The washer 362 has an annular shape surrounding a washer hole in the circumferential direction around the z direction. The shaft portion is passed through the washer hole. The washer 362 is provided on the seventh connection part 341 side so as to contact the seventh connection part 341.

The nut 363 has an annular shape surrounding a nut hole in the circumferential direction around the z direction. A groove is formed on the inner surface defining the nut hole so as to fit into the groove formed on the shaft portion. The shaft portion is passed through the nut hole. The nut 363 is provided on the seventh connection part 341 side so as to contact the washer 362.

Thus, the first power supply bus bar 330 and the second power supply bus bar 340 are electrically and mechanically connected by the joint portion 360.

It is possible to deal with vehicles with different required current values by appropriately changing the cross-sectional area cut by a plane along the main surface direction and the side surface direction perpendicular to the extension direction of the second power supply bus bar 340. A tool gap can be widely secured at that time.

The joint portion 360 may not have the bolt 361, the washer 362 and the nut 363. The joint portion 360 may be done by, for example, a crimp.

Also, the first power supply bus bar 330 and the second power supply bus bar 340 may be joined by welding. In this case, the contact area between the second main surface 330b of the first power supply bus bar 330 and the fourth main surface 340b of the second power supply bus bar 340 tends to decrease. Therefore, the heat resistance at the joint portion 360 tends to increase. Heat is less likely to be conducted from the first power supply bus bar 330 to the second power supply bus bar 340.

### <Operation and Effects>

As described above, the cross-sectional area cut by the plane along each of the main surface direction and the side surface direction of the first power supply bus bar 330 is larger than the cross-sectional area cut by any plane along each of the main surface direction and the side surface direction of the second power supply bus bar 340.

The thermal resistance per unit length in the extension direction of the second power supply bus bar 340 is higher than the thermal resistance per unit length in the extension direction of the first power supply bus bar 330.

Therefore, heat is less likely to be conducted to the first capacitor 380. The temperature rise of the first capacitor 380 is easily suppressed.

As described above, the addition average of the thermal resistance per unit length in the extension direction of the second conductive section 320 and the thermal resistance per unit length in the extension direction of the second power supply bus bar 340 is higher than the thermal resistance per unit length in the extension direction of the first conductive connection portion 313. Therefore, heat is less likely to be conducted to the first capacitor 380.

Furthermore, the addition average of the thermal resistance per unit length in the extension direction of the second conductive section 320 and the thermal resistance per unit length in the extension direction of the second power supply bus bar 340 is higher than the thermal resistance per unit length in the extension direction of the second conductive connection portion 319. Similarly, heat is less likely to be conducted to the first capacitor 380.

As described above, the cross-sectional areas cut by a plane along each of the main surface direction and the side surface direction of each of the first tip part 345 and the second tip part 346 is smaller than the cross-sectional area cut by a plane along each of the main surface direction and the side surface direction of the tenth connection part 344.

Therefore, the thermal resistance per unit length in the extension direction of the first tip part 345 and the second tip part 346 is higher than the thermal resistance per unit length in the extension direction of the tenth connection portion 344. According to this configuration, it is difficult to transfer heat to the first capacitor 380.

Furthermore, each of the first tip part 345 and the second tip part 346 is easily soldered to one of the two electrodes of the first capacitor 380.

Furthermore, the addition average of the electrical resistance per unit length in the extension direction of the second conductive section 320 and the electrical resistance per unit length in the extension direction of the second power supply bus bar 340 is higher than the electrical resistance per unit length in the extension direction of the second conductive connection portion 319.

Therefore, the current supplied from the battery 200 easily flows through the second conductive connection portion 319.

As described above, the second conductive connection portion 319 is connected to the reactor 520 by the second connection bus bar 712. The reactor 520 boosts the DC power of the battery 200 by storing and discharging power.

Since the current supplied from the battery 200 easily flows through the second conductive connection portion 319, the charging and discharging of the reactor 520 are less likely to be suppressed. It is becoming difficult to suppress the boost of the DC power.

As described above, the first power supply bus bar 330 and the second power supply bus bar 340 are electrically and mechanically connected by the joint portion 360.

The joint portion 360 increases the thermal resistance of the combined portion of the second conductive section 320 and the second power supply bus bar 340. According to this configuration, it is difficult to transfer heat to the first capacitor 380.

### (First Modification)

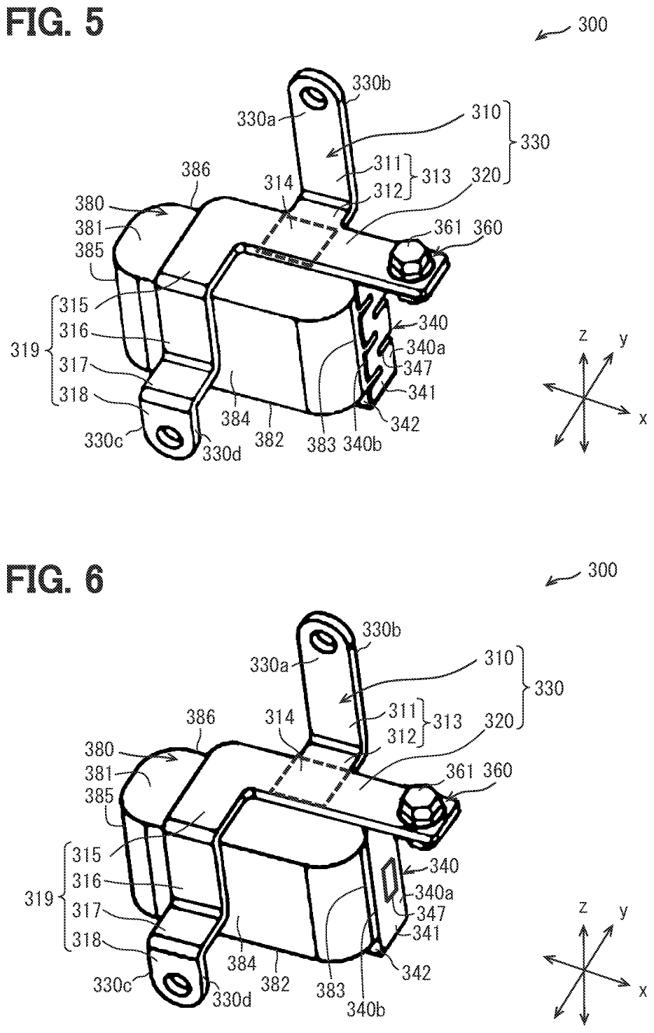

As shown in FIG. 5, a plurality of notches 347 may be formed in the second power supply bus bar 340 to increase thermal resistance per unit length in the extension direction.

For example, the notch 347 may be recessed from the third side surface 340c toward the fourth side surface 340d. The notch 347 may be formed so as to be recessed from the fourth side surface 340d toward the third side surface 340c. In that case, the size of the cross-sectional area cut by a plane along the main surface direction and the side surface direction perpendicular to the extension direction of the second power supply bus bar 340 and the side surface direction becomes smaller. Along with this configuration, the thermal resistance per unit length in the extension direction of the second power supply bus bar 340 is reduced.

### (Second Modification)

As shown in FIG. 6, the notch 347 may not be notched in the side surface direction. The notch 347 may be cut in the main surface direction. A through hole may be formed through the third main surface 340a and the fourth main surface 340b.

### (Third Modification)

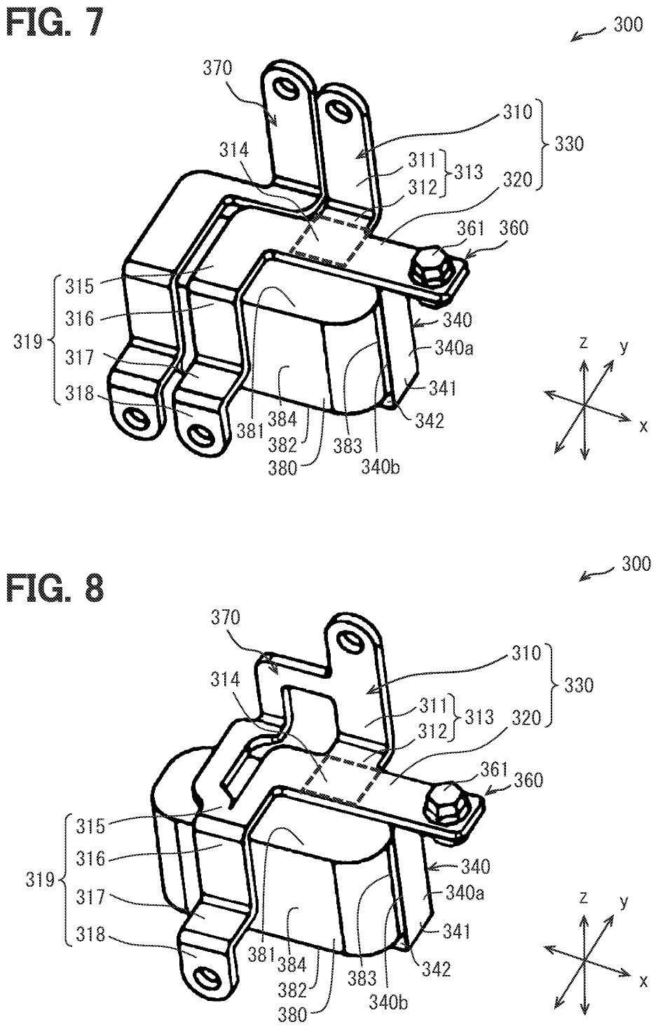

As shown in FIG. 7, there may be a fourth power supply bus bar 370 that electrically connects the battery 200 and the electrical component 800 via a conductive path different from first power supply bus bar 330. In that case, the amount of current flowing through the first power supply bus bar 330 tends to decrease. Therefore, self-heating of the first power supply bus bar 330 is easily suppressed. As a result, heat is less likely to be conducted to the first capacitor 380. The fourth power supply bus bar 370 corresponds to a separate path portion.

### (Fourth Modification)

As shown in FIG. 8, the fourth power supply bus bar 370 may be integrally connected to the first power supply bus bar 330. In this case, self-heating of the first power supply bus bar 330 can be suppressed without increasing the number of parts.

What is claimed is:

1. An electric device, comprising:
a first power supply portion having a first conductive section configured to electrically connect a power source and an electrical component and a second conductive section configured to extend from the first conductive section;
a second power supply portion connected to the second conductive section; and
a capacitor connected to the second power supply portion, wherein
the first power supply portion and the second power supply portion extend along the capacitor so as to face each other, and
a thermal resistance per unit length in a second extension direction of the second power supply portion is higher than a thermal resistance per unit length in a first extension direction of the first power supply portion.

2. The electric device according to claim 1, wherein
the first conductive section includes a first conductive connection portion connected to the power source, a second conductive connection portion connected to the electrical component, and a connection portion configured to connect the first conductive connection portion and the second conductive connection portion and connect to the second conductive section, and
an addition average of a thermal resistance per unit length in a first extension direction of the second conductive section and the thermal resistance per unit length in a second extension direction of the second power supply portion is higher than each of the thermal resistance per unit length in the first extension direction of the first conductive connection portion and the thermal resistance per unit length in the first extension direction of the second conductive connection portion.

3. The electric device according to claim 1, wherein
a second cross-sectional area cut by a plane along a direction perpendicular to the second extension direction of the second power supply portion is smaller than a first cross-sectional area cut by a plane along a direction perpendicular to the first extension direction of the first power supply portion.

4. The electric device according to claim 3, wherein
the second cross-sectional area of the portion of the second power supply portion connected to the capacitor is smaller than the second cross-sectional area of the portion between the portion of the second power supply portion connected to the capacitor and the portion of the second power supply portion connected to the first power supply portion.

5. The electric device according to claim 1, wherein
the first power supply portion has a first main surface and a second main surface arranged in a first orthogonal direction perpendicular to the first extension direction, and a first side surface and a second side surface aligned in a second orthogonal direction orthogonal to each of the first extension direction and the first orthogonal direction, and
the second power supply portion has a third main surface and a fourth main surface arranged in a third orthogonal direction perpendicular to the second extension direction, and a third side surface and a fourth side surface aligned in a fourth orthogonal direction orthogonal to each of the second extension direction and the fourth orthogonal direction.

6. The electric device according to claim 5, wherein
the fourth main surface is soldered to the capacitor, and
a distance between the third main surface and the fourth main surface in the third orthogonal direction is shorter than a distance between the first main surface and the second main surface in the first orthogonal direction.

7. The electric device according to claim 1, wherein
the second power supply portion is formed with a notch so as to increase a thermal resistance per unit length.

8. The electric device according to claim 1, further comprising
a separate path portion configured to electrically connect the power source and the electrical component via a conductive path different from the first conductive section.

9. The electric device according to claim 8, wherein
the separate path portion is integrally connected to the first conductive section.

10. The electric device according to claim 1, further comprising
a joint portion configured to join the first power supply portion and the second power supply portion.

11. The electric device according to claim 1, wherein
the electrical component has a reactor connected to the first power supply portion.
